(19) United States
(12) Patent Application Publication
(10) Pub. No.: US 2023/0343622 A1
(43) Pub. Date: Oct. 26, 2023

(54) STAGE APPARATUS, CHARGED PARTICLE BEAM APPARATUS, AND OPTICAL INSPECTION APPARATUS

(71) Applicant: Hitachi High-Tech Corporation, Tokyo (JP)

(72) Inventors: Takanori KATO, Tokyo (JP); Masaki MIZUOCHI, Tokyo (JP); Motohiro TAKAHASHI, Tokyo (JP); Hironori OGAWA, Tokyo (JP)

(21) Appl. No.: 18/127,020

(22) Filed: Mar. 28, 2023

(30) Foreign Application Priority Data
Apr. 20, 2022 (JP) 2022-069576

(51) Int. Cl. H01L 21/673; H01L 21/687; H01L 21/68

(52) U.S. Cl. CPC H01L 21/67346; H01L 21/6875; H01L 21/68764; H01L 21/681

(57) ABSTRACT

Provided is a stage apparatus including: a first table that is movable on a base; a second table that is movable in a state of floating above the first table and includes a first portion and a second portion below the first portion; a first position measuring device that measures a position of the first portion of the second table; a second position measuring device that measures a position of the second portion of the second table; and a computer that controls a motor that drives the second table. The computer drives the second table based on information on the position of the first portion measured by the first position measuring device and information on the position of the second portion measured by the second position measuring device.

### CLAIM OF PRIORITY

The present application claims priority from Japanese Patent Application JP 2022-069576 filed on Apr. 20, 2022, the content of which is hereby incorporated by reference into this application.

### BACKGROUND OF THE INVENTION

### 1. Field of the Invention

The present invention relates to a stage apparatus, a charged particle beam apparatus including the stage apparatus, and an optical inspection apparatus.

### 2. Description of the Related Art

In processes such as semiconductor manufacturing, measurement, and inspection, an XY stage is used for a stage apparatus in order to accurately determine a position of a semiconductor device such as a wafer. As the stage apparatus, a stack-type stage apparatus in which two stages of tables (an X table and a Y table) are stacked and disposed in a vertical direction may be used.

Examples of a drive mechanism of the XY stage include a mechanism driven by a rotation motor and a ball screw using a linear guide and a mechanism driven using a linear motor. In addition, a stage that performs not only a motion in an XY plane but also a motion parallel to a Z axis or a rotational motion about the Z axis may be used for positioning the semiconductor device. In particular, in recent years, a non-contact type floating stage using a static pressure bearing or an electromagnetic force is often used in order to realize ultra-precise positioning.

In the stack-type stage apparatus, a configuration may be used in which only an upper table is configured as a floating stage and a lower table is guided by a linear guide, or a configuration in which both upper and lower tables are used as floating stages. In this case, in order to realize highly accurate positioning, a configuration is adopted in which the upper table (floating stage) is driven by a drive mechanism in six-axial directions (translation directions of X, Y, and Z and rotation directions of θx, θy, and θz) with excellent controllability, and the center of gravity of the upper table is controlled in the six-axial directions.

Methods for detecting the position of the floating stage include a method using an optical sensor and a method using a laser interferometer. In the method using the optical sensor (for example, linear scale), for example, a scale unit of the linear scale is disposed on a lower table, a light receiving unit is disposed on an upper table, and relative positions of these two tables are detected, thereby detecting the position of the floating stage. In the method using the laser interferometer, the position of the floating stage is detected by interference between laser light and reflected waves using a laser interferometer and a reflecting mirror. By performing feedback control using the position detected by these methods, the position of the floating stage can be controlled with high accuracy.

An example of a stack-type stage apparatus including a floating stage is described in JP 2019-179879 A. A stage apparatus described in JP 2019-179879 A includes a linear motor that generates a thrust in a driving direction (Y direction) of the stage, and a yoke that covers the linear motor. A floating portion includes a permanent magnet and an electromagnet, and a floating force in a z direction is obtained by using the linear motor for the driving direction.

### SUMMARY OF THE INVENTION

In the stack-type stage apparatus including the floating stage, a height position of the center of gravity is essentially different between the upper table (floating stage) and the lower table. In general, the drive mechanism of the floating stage controls the height position of the center of gravity of the floating stage in order to improve a positional accuracy. Therefore, a drive reaction force when the floating stage (upper table) is driven is applied to a height position different from the height position of the center of gravity of the lower table, and a rotational moment is generated in the lower table.

Here, an influence of a rotational vibration of the lower table is considered by exemplifying a case where the position of the floating stage is measured by using the linear scale. A component (minute components on the order of nanometers) caused by the rotational vibration of the lower table is superimposed on a signal (signal indicating the position of the floating stage) measured by the linear scale. When tracking control of the floating stage is performed by using a position signal on which the minute component (the rotational vibration of the lower table) is superimposed, the tracking control of the floating stage is performed in accordance with the rotational vibration of the lower table, and the rotational vibration of the floating stage increases. In addition, since the drive reaction force at the time of the tracking control of the floating stage acts on the lower table, the rotational vibration of the lower table is further increased.

As described above, the conventional technique such as the technique disclosed in JP 2019-179879 A can control the floating stage with a simple configuration, but has a problem that residual vibration (vibration remaining on the floating stage after movement of the floating stage) of the floating stage increases due to the rotational vibration of the lower table. When the residual vibration of the floating stage increases, a time for waiting for the residual vibration to attenuate becomes long, and it is difficult to improve throughput of the stage apparatus.

An object of the present invention is to provide a stage apparatus capable of reducing residual vibration of a floating stage (upper table) accompanying rotational vibration of a lower table and improving throughput, a charged particle beam apparatus including the stage apparatus, and an optical inspection apparatus.

A stage apparatus according to the present invention includes: a base; a first table that is movable on the base; a second table that is movable in a state of floating above the first table and includes a first portion and a second portion below the first portion; a first position measuring device that measures a position of the first portion of the second table; a second position measuring device that measures a position of the second portion of the second table; a motor that drives the second table; and a computer that controls the motor. The computer drives the second table based on information on the position of the first portion measured by the first position measuring device and information on the position of the second portion measured by the second position measuring device.

A stage apparatus according to the present invention may have a configuration including a base, a first table movable on the base, a second table movable in a state of floating above the first table, a position measuring device that measures a relative position of the second table with respect to the first table, a motor that drives the second table, and a computer that controls the motor. A frequency of rotational vibration of the first table is known in advance, the computer stores information on the frequency, and the computer performs filter processing of removing a component of the frequency from a measurement value of the position measuring device, and drives the second table by using the measurement value of the position measuring device subjected to the filter processing.

A charged particle beam apparatus according to the present invention includes a stage apparatus, a chamber that accommodates the stage apparatus, and a lens barrel that is installed in the chamber and includes a charged particle beam source. The stage apparatus is the above-described stage apparatus.

An optical inspection apparatus according to the present invention includes a stage apparatus, a chamber that accommodates the stage apparatus, and a lens barrel that is installed in the chamber and includes a light source. The stage apparatus is the above-described stage apparatus.

According to the present invention, it is possible to provide a stage apparatus capable of reducing residual vibration of the floating stage (upper table) accompanying rotational vibration of the lower table and improving the throughput, a charged particle beam apparatus including the stage apparatus, and an optical inspection apparatus.

### BRIEF DESCRIPTION OF THE DRAWINGS

FIG. 1 is a diagram illustrating an example of a configuration of a conventional stack-type stage apparatus;

FIG. 2 is a diagram illustrating an example of a configuration of a conventional stack-type stage apparatus including a floating stage;

FIG. 3 is a diagram illustrating an example of a method of measuring a relative position of an X table which is a floating stage;

FIG. 4A is a diagram illustrating an example of an influence of rotational vibration of a Y table on an X table in the conventional stack-type stage apparatus including the floating stage;

FIG. 4B is a diagram illustrating an example of a posture of the X table when the rotational vibration is generated in the Y table in the stage apparatus according to an embodiment of the present invention;

FIG. 5A is a graph illustrating an example of a waveform of vibration of an X table in a case where only the X table is driven;

FIG. 5B is a graph illustrating an example of a waveform of vibration of the X table in a case where the X table and the Y table are simultaneously driven;

FIG. 6 is a diagram illustrating a configuration of a stage apparatus according to a first embodiment of the present invention;

FIG. 7 is a graph illustrating a difference in frequency characteristics between a measurement value of a linear scale and a measurement value of laser interference with respect to the rotational vibration of the Y table;

FIG. 8 is a diagram illustrating a flowchart of processing of moving the X table that is a floating stage by the stage apparatus according to the first embodiment;

FIG. 9A is a diagram illustrating an example of a measurement value of a linear scale before a computer system performs filter processing;

FIG. 9B is a diagram illustrating an example of filter frequency characteristics of the filter processing performed by the computer system;

FIG. 9C is a diagram illustrating an example of a measurement value of a linear scale after the computer system performs the filter processing;

FIG. 10 is a diagram illustrating a configuration of a stage apparatus according to a second embodiment of the present invention;

FIG. 11 is a diagram illustrating an example of a vibration frequency map in which information on the frequency of the rotational vibration of the Y table is recorded;

FIG. 12 is a diagram illustrating a flowchart of processing of moving the X table that is a floating stage by the stage apparatus according to the second embodiment;

FIG. 13 is a diagram illustrating a configuration of a stage apparatus according to a third embodiment of the present invention;

FIG. 14 is a diagram illustrating a configuration of a stage apparatus according to a fourth embodiment of the present invention; and

FIG. 15 is a diagram illustrating a configuration example of a charged particle beam apparatus or an optical inspection apparatus according to a fifth embodiment of the present invention.

### DESCRIPTION OF THE PREFERRED EMBODIMENTS

A stage apparatus according to the present invention is a stack-type stage apparatus in which two tables are disposed in a vertical direction, in which at least an upper table is configured by a floating stage, vibration (for example, residual vibration) of the upper table (floating stage) accompanying rotational vibration of a lower table can be reduced, and throughput can be improved.

First, a stack-type stage apparatus will be described with reference to the drawings. Hereinafter, directions orthogonal to each other in a horizontal plane are defined as an X direction and a Y direction, and a direction perpendicular to the horizontal plane is defined as a Z direction or a height direction. The X direction, the Y direction, and the Z direction may be referred to as an X axis direction, a Y axis direction, and a Z axis direction, respectively. In the drawings used in the present specification, the same or corresponding components are denoted by the same reference numerals, and repeated description of these components may be omitted.

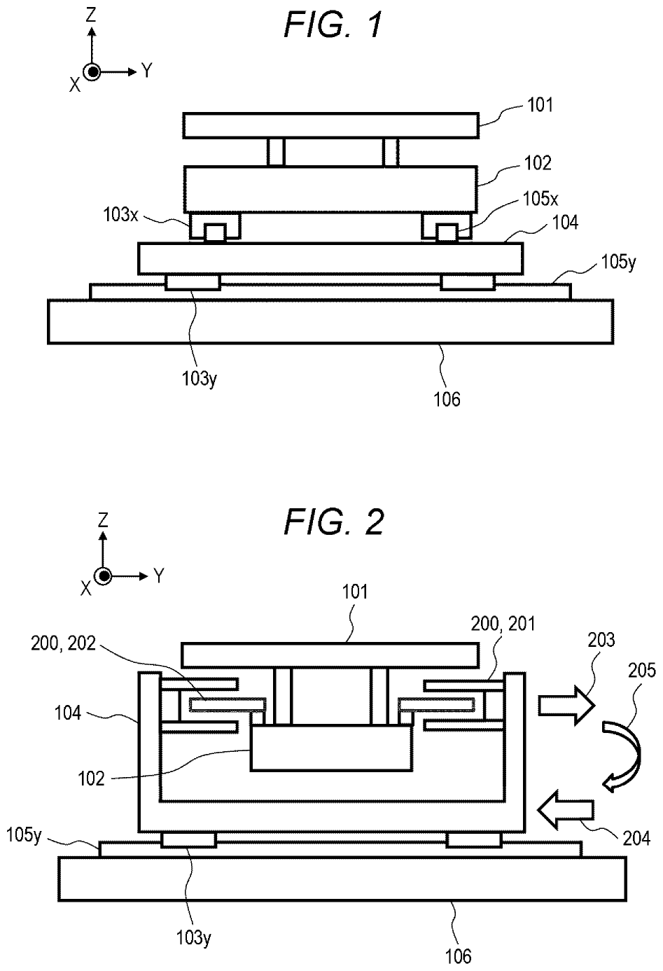

FIG. 1 is a diagram illustrating an example of a configuration of a conventional stack-type stage apparatus. The stage apparatus illustrated in FIG. 1 is also referred to as an XY stage, and includes a base 106, a Y table 104 which is a lower table, and an X table 102 which is an upper table. The X table 102 includes a top table 101 in an upper portion.

The base 106 is a member that supports the Y table 104 and the X table 102.

The Y table 104 is positioned above the base 106 via a linear guide 105y and a guide carriage 103y. The Y table 104 is driven by a Y linear motor (not illustrated) and is movable on the base 106 in the Y direction (direction parallel to a paper surface). The Y linear motor is disposed between the base 106 and the Y table 104, and generates a thrust for moving the Y table 104 in the Y direction.

A linear scale (not illustrated) for measuring a relative position between the base 106 and the Y table 104 is disposed on the base 106 and the Y table 104. The linear scale measures a relative displacement amount in the Y direction of the Y table 104 with respect to the base 106.

The X table 102 is positioned above the Y table 104 via a linear guide 105x and a guide carriage 103x. The X table 102 is driven by an X linear motor (not illustrated) and is movable above the Y table 104 in the X direction (direction perpendicular to the paper surface). The X linear motor is disposed between the Y table 104 and the X table 102, and generates a thrust for moving the X table 102 in the X direction.

In the Y table 104 and the X table 102, a linear scale (not illustrated) for measuring the relative position between the Y table 104 and the X table 102 is disposed. The linear scale measures a relative displacement amount in the X direction of the X table 102 with respect to the Y table 104.

An object such as a semiconductor wafer is placed on an upper surface of the top table 101. A position of the object such as the semiconductor wafer can be determined by moving the X table 102 and the Y table 104 on the XY plane.

Next, a stack-type stage apparatus including a floating stage and rotational vibration of the Y table 104 which is a lower table will be described.

FIG. 2 is a diagram illustrating an example of a configuration of a conventional stack-type stage apparatus including a floating stage. In the stage apparatus illustrated in FIG. 2, the Y table 104 is movable in the Y direction via the linear guide 105y and the guide carriage 103y, similarly to the conventional stage apparatus (XY stage) illustrated in FIG. 1. Hereinafter, a configuration of the stage apparatus illustrated in FIG. 2 different from the stage apparatus illustrated in FIG. 1 will be mainly described.

The X table 102 is a floating stage that obtains a floating force and a propulsive force by a thrust of electromagnetic force. The X table 102 is driven by obtaining a thrust in the Y direction by a motor 200. The motor 200 includes a Y motor yoke 201 disposed on the Y table 104 and a Y motor coil 202 disposed on the X table 102, and moves the X table 102. The X table 102 is driven not only by the motor 200 but also by a plurality of motors (not illustrated) that generate a thrust in six-axial directions, and a posture thereof is controlled in six degrees of freedom. The six-axial directions are directions of an X axis, a Y axis, a Z axis, a θx axis, a θy axis, and a θz axis. The θx axis, the θy axis, and the θz axis are directions about the X axis, the Y axis, and the Z axis, respectively.

The plurality of motors for driving the X table 102, which is the floating stage, are generally disposed so as to apply the thrust to a drive center of gravity of the floating stage so that the position of the top table 101 can be determined with high accuracy.

In the stage apparatus as illustrated in FIG. 2, rotational vibration is generated in the Y table 104 when the X table 102 is driven and when the Y table 104 is driven as follows.

In the stage apparatus illustrated in FIG. 2, unlike the conventional XY stage (FIG. 1), the X table 102 is driven by generating the thrust in the Y direction. When the X table 102 is driven, a drive reaction force 203 of the thrust acts on the Y table 104 via the Y motor yoke 201. Since the drive reaction force 203 acts on a height position different from the height position (position in the height direction) of the center of gravity of the Y table 104, rotational vibration (in particular, rotational vibration about the X axis) is generated in the Y table 104.

When the Y table 104 is driven to position the Y table 104, a driving force 204 of the Y table 104 acts in a direction opposite to the drive reaction force 203, so that rotational vibration about the X axis is generated in the Y table 104 by a rotational moment 205 about the X axis.

FIG. 2 illustrates an example in which the Y table 104 moves via the linear guide 105y and the guide carriage 103y. Even when the Y table 104 is a floating stage, in the stack-type stage apparatus, the height position of the center of gravity is essentially different between the upper table (X table 102) and the lower table (Y table 104), so that rotational vibration similar to that in the example illustrated in FIG. 2 is generated in the Y table 104.

In the Y table 104, rotational vibration about the Y axis may be generated by the rotational moment about the Y axis, or rotational vibration about the Z axis may be generated by the rotational moment about the Z axis. In the following description, as a representative example, a case where rotational vibration about the X axis is generated on the Y table 104 by the rotational moment 205 about the X axis will be described.

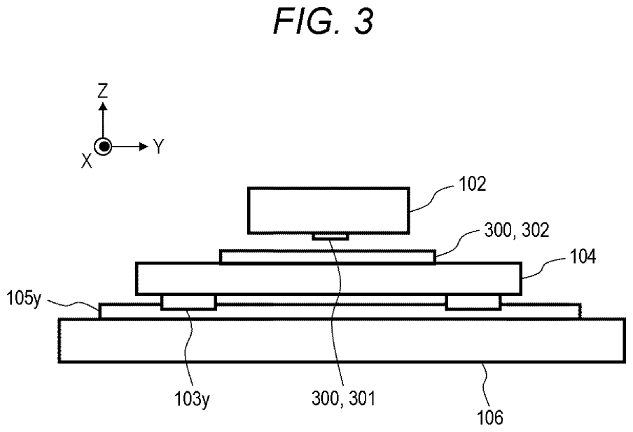

FIG. 3 is a diagram illustrating an example of a method of measuring a relative position of the X table 102 which is a floating stage. FIG. 3 illustrates, as an example, a method of measuring the position of the X table 102 by using a linear scale 300 which is an optical sensor. As the sensor that measures the position of the X table 102, an optical sensor other than the linear scale 300 or a position sensor using electrostatic capacitance may be used.

The linear scale 300 includes a light source that emits light, a scale unit 302 that reflects the light from the light source, and a light receiving unit 301 that reads the light reflected by the scale unit 302. In the linear scale 300 illustrated in FIG. 3, as an example, the light receiving unit 301 includes a light source.

The scale unit 302 is installed on an upper portion (upper surface) of the Y table 104. The light receiving unit 301 is installed at a lower portion (lower surface) of the X table 102. With such a disposition, the linear scale 300 can measure the relative position of the X table 102 with respect to the Y table 104. In addition, the X table 102 may include six or six or more linear scales (not illustrated) for detecting the posture of the X table 102 in the six-axial directions. A measurement value of the linear scale 300 is used for feedback control calculation for driving the X table 102.

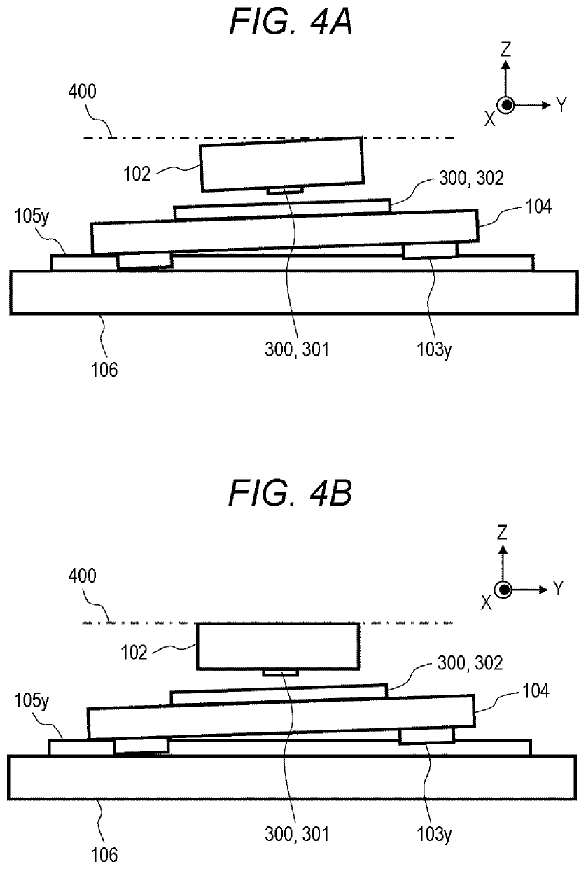

FIG. 4A is a diagram illustrating an example of an influence of the rotational vibration of the Y table 104 on the X table 102 in the conventional stack-type stage apparatus including the floating stage.

When the rotational vibration is generated in the Y table 104, a component of the rotational vibration of the Y table 104 is superimposed on the measurement value of the linear scale 300. When the tracking control is performed on the X table 102, which is the floating stage, using this measurement value, the X table 102 is feedback-controlled so that the displacement amount relative to the Y table 104 becomes zero, and thus rotational vibration is generated in the X table 102 following the rotational vibration of the Y table 104. Since this rotational vibration tilts the X table 102 with respect to a horizontal plane 400 as illustrated in FIG. 4A to lower the positioning accuracy of the X table 102, the time until the vibration (residual vibration) attenuates becomes a waiting time to lower the throughput of the stage apparatus.

FIG. 4B is a diagram illustrating an example of the posture of the X table 102 when the rotational vibration is generated in the Y table 104 in the stage apparatus according to the embodiment of the present invention. In the stage apparatus according to the embodiment of the present invention, as described below, since the influence of the rotational vibration can be reduced even when the rotational vibration is generated in the Y table 104, the X table 102 can maintain an ideal posture (for example, a posture in which the X table 102 is parallel to the horizontal plane 400 as illustrated in FIG. 4B), and the throughput of the stage apparatus can be improved.

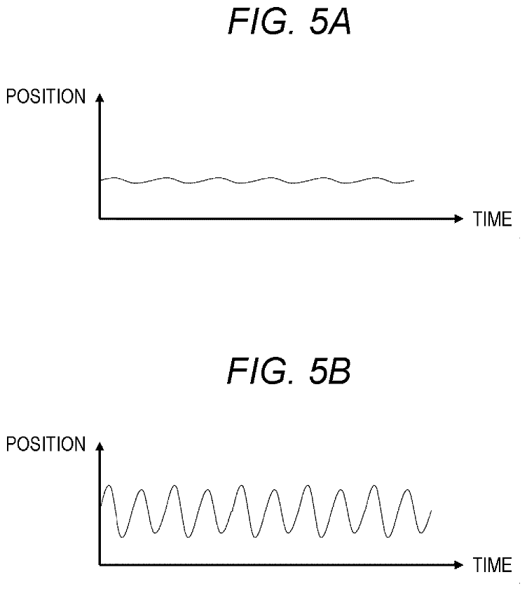

FIGS. 5A and 5B are graphs illustrating an example of a waveform of the vibration of the X table 102 which is a floating stage.

FIG. 5A illustrates an example of a waveform of the vibration of the X table 102 in a case where only the X table 102 is driven. Since only the X table 102 is driven, only the drive reaction force 203 (FIG. 2) acts on the Y table 104. In the X table 102, the rotational vibration of the Y table 104 generated only by the drive reaction force 203 generates vibration as illustrated in FIG. 5A.

FIG. 5B illustrates an example of a waveform of the vibration of the X table 102 in a case where the X table 102 and the Y table 104 are simultaneously driven. In this case, since the driving force 204 (FIG. 2) acts on the Y table 104 to generate the rotational moment 205 about the X axis, the rotational vibration of the Y table 104 is increased more than the case where only the X table 102 is driven. Therefore, as illustrated in FIG. 5B, vibration larger than the vibration illustrated in FIG. 5A is generated in the X table 102.

That is, when the X table 102 and the Y table 104 are simultaneously driven, the vibration of the X table 102 due to the rotational vibration of the Y table 104 increases as compared with the case where only the X table 102 is driven.

Hereinafter, a stage apparatus, a charged particle beam apparatus, and an optical inspection apparatus according to embodiments of the present invention will be described with reference to the drawings.

### First Embodiment

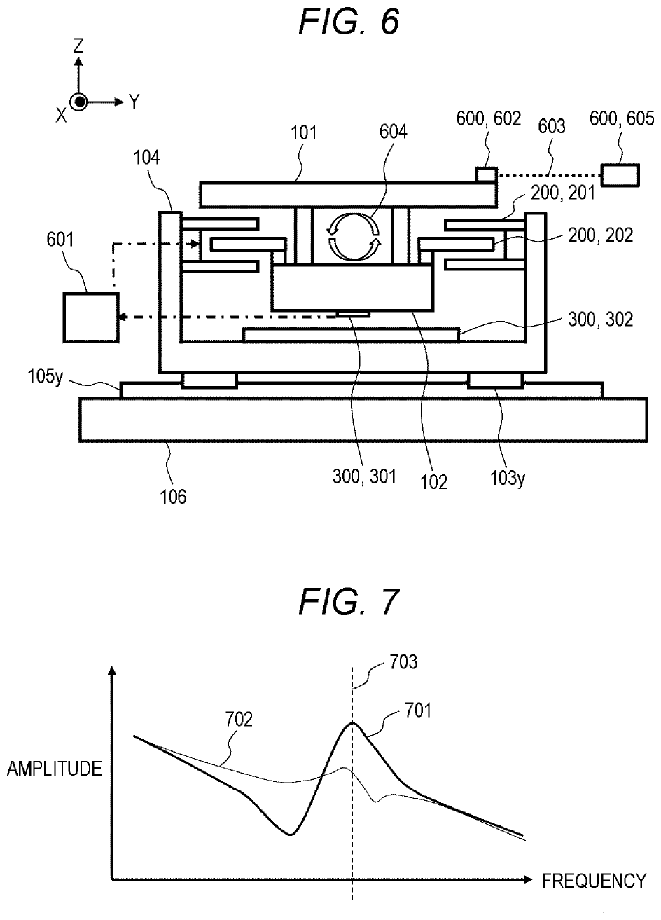

FIG. 6 is a diagram illustrating a configuration of a stage apparatus according to a first embodiment of the present invention. The stage apparatus according to the present embodiment is a stack-type stage apparatus including a floating stage. Hereinafter, a configuration of the stage apparatus according to the present embodiment different from the conventional stage apparatus illustrated in FIG. 2 will be mainly described.

The stage apparatus according to the present embodiment includes a first position measuring device that measures a position of a first portion of the X table 102, a second position measuring device that measures a position of a second portion of the X table 102, and a computer system 601. The first portion of the X table 102 is an upper surface of the top table 101. That is, the position of the first portion of the X table 102 is a position close to a position of an object (for example, a semiconductor wafer or the like) placed on the top table 101, and is a position above a rotation center 604 of the X table 102. The second portion of the X table 102 is a portion below the first portion and below the rotation center 604 of the X table 102 in the X table 102. The rotation center 604 of the X table 102 is a rotation center while the X table 102 is floating.

The first position measuring device is, for example, a laser interferometer 600. The laser interferometer 600 includes a light source 605 that emits laser light 603 and a reflecting mirror 602 installed on the upper surface of the top table 101. The laser interferometer 600 measures the position of the X table 102 in the Y direction and the Z direction based on the interference between the laser light 603 emitted from the light source 605 and the reflected light of the laser light 603 by the reflecting mirror 602. Although FIG. 6 illustrates a configuration in which the laser interferometer 600 measures the position of the X table 102 in the Y direction, the laser interferometer 600 can include a configuration (for example, a reflecting mirror (not illustrated)) for measuring the position of the X table 102 in the X direction, and can measure the position of the X table 102 in the X direction and the Z direction.

By using the laser interferometer 600, measurement can be performed at a position close to the position of the object (for example, a semiconductor wafer or the like) placed on the top table 101, and the position of the X table 102 on which the object is placed can be measured with high accuracy with less Abbe error. As the first position measuring device, instead of the laser interferometer 600, a planar scale disposed on the top table 101 can also be used.

The second position measuring device is, for example, the linear scale 300. The linear scale 300 measures the relative position of the X table 102 with respect to the Y table 104.

The computer system 601 is a device configured by a computer, and executes calculation, control, and the like related to the stage apparatus. For example, the computer system 601 moves the X table 102 by controlling the motor 200. The computer system 601 performs feedback control calculation by using the information on the position of the X table 102 measured by the laser interferometer 600 and the information on the position of the X table 102 measured by the linear scale 300, and drives the motor 200 to generate the floating force and the propulsive force of the X table 102 and control the X table 102.

The X table 102 is a floating stage, and moves or changes the posture under the control of the computer system 601. When floating, the X table 102 is subject to the tracking control in accordance with the rotational vibration of the Y table 104, and may generate the rotational vibration. The center of the rotational vibration is the rotation center 604 of the X table 102.

The laser interferometer 600, which is the first position measuring device, measures the position of the first portion of the X table 102. The linear scale 300, which is the second position measuring device, measures the position of the second portion of the X table 102. That is, the laser interferometer 600 is installed so as to measure a position of a portion above the rotation center 604 of the X table 102, and the linear scale 300 is installed so as to measure a position of a portion below the rotation center 604 of the X table 102.

With such a configuration in which the laser interferometer 600 and the linear scale 300 are positioned at positions opposite to each other with respect to the rotation center 604 of the X table 102 in the height direction, the stage apparatus according to the present embodiment can measure the vibration of the X table 102 in phases opposite to each other by the laser interferometer 600 and the linear scale 300 when the rotational vibration is generated on the Y table 104. That is, in the stage apparatus according to the present embodiment, a sign of the measurement value of the laser interferometer 600 and a sign of the measurement value of the linear scale 300 change inversely with each other.

The computer system 601 calculates the frequency of the rotational vibration of the Y table 104 by using a method described later with reference to FIG. 7. The stage apparatus according to the present embodiment may calculate the frequency of the rotational vibration of the Y table 104 in real time at high speed by using a field-programmable gate array (FPGA), or may calculate the frequency offline by using a computer system other than the computer system 601.

As a method of preventing the vibration of the X table 102 due to the rotational vibration of the Y table 104, for example, there is a method of performing filter processing of removing a frequency component of the rotational vibration of the Y table 104 from a measurement value of the linear scale 300 (a signal of a relative position of the X table 102 with respect to the Y table 104). The calculation of the filter processing may be executed by the computer system 601 as digital processing or may be executed by using the FPGA.

The computer system 601 can reduce the influence of the rotational vibration of the Y table 104 on the X table 102 by controlling the X table 102 by using the position signal (measurement value of the linear scale 300) from which the frequency component of the rotational vibration of the Y table 104 has been removed. That is, the computer system 601 can reduce the residual vibration of the X table 102 (floating stage) accompanying the rotational vibration of the Y table 104.

As another method of reducing the influence of the rotational vibration of the Y table 104 on the X table 102, there is the following method. That is, the computer system 601 may calculate a drive signal for offsetting the frequency component of the rotational vibration of the Y table 104 with respect to the motor 200 of the X table 102, and may drive the X table 102 by applying the drive signal to the motor 200. The computer system 601 can control the X table 102 with a signal from which the frequency component of the rotational vibration of the Y table 104 has been removed by applying this drive signal to the motor 200.

FIG. 7 is a graph illustrating a difference in frequency characteristics between the measurement value of the linear scale 300 and the measurement value of the laser interferometer 600 with respect to the rotational vibration of the Y table 104. A method in which the computer system 601 calculates the frequency of the rotational vibration of the Y table 104 will be described with reference to FIG. 7.

A scale vibration characteristic 701 is a frequency characteristic of the vibration of the X table 102 measured by using the linear scale 300. The scale vibration characteristic 701 can be obtained by converting a measurement signal of the linear scale 300, that is, a temporal change (amplitude) of the position of the X table 102 measured by the linear scale 300 into a frequency domain.

A laser vibration characteristic 702 is a frequency characteristic of the vibration of the X table 102 measured by using the laser interferometer 600. The laser vibration characteristic 702 can be obtained by converting a measurement signal of the laser interferometer 600, that is, a temporal change (amplitude) of the position of the X table 102 measured by the laser interferometer 600 into a frequency domain.

The linear scale 300 measures the position of the X table 102 with reference to the Y table 104. Therefore, the measurement value of the linear scale 300, that is, the scale vibration characteristic 701 includes a lot of information on the rotational vibration of the Y table 104. On the other hand, the laser interferometer 600 directly measures the position of the X table 102 without using the Y table 104 as a reference. Therefore, the measurement value of the laser interferometer 600, that is, the laser vibration characteristic 702 does not include much information on the rotational vibration of the Y table 104.

Therefore, the scale vibration characteristic 701 has a vibration amplitude larger than that of the laser vibration characteristic 702. The amplitude of the scale vibration characteristic 701 is considered to be the largest at the frequency of the rotational vibration of the Y table 104.

As described above, in the stage apparatus according to the present embodiment, when the rotational vibration is generated in the Y table 104, the laser interferometer 600 and the linear scale 300 detect vibration of the X table 102 in phases opposite to each other. That is, the sign of the measurement value of the laser interferometer 600 and the sign of the measurement value of the linear scale 300 change opposite to each other, and the scale vibration characteristic 701 and the laser vibration characteristic 702 have an opposite phase relationship as illustrated in FIG. 7.

As described above, the computer system 601 can set the frequency at which the scale vibration characteristic 701 and the laser vibration characteristic 702 are in the opposite phase relationship (relationship in which the measurement signal of laser interferometer 600 and measurement signal of linear scale 300 have an opposite phase relationship) and the amplitude of the scale vibration characteristic 701 is the largest as a frequency 703 of the rotational vibration of the Y table 104.

The computer system 601 can obtain the phase of the vibration of the X table 102 and the frequency 703 of the rotational vibration of the Y table 104 in a case where the rotational vibration is generated in the Y table 104 by using, for example, Fourier transform or the like. Specifically, the computer system 601 can calculate the frequency 703 of the rotational vibration of the Y table 104 by executing Fourier transform on the signal of the measurement value of the linear scale 300 and the signal of the measurement value of the laser interferometer 600, obtaining the frequency characteristics (the scale vibration characteristic 701 and the laser vibration characteristic 702) of the vibration of the X table 102 as illustrated in FIG. 7, and calculating the phases and amplitudes of the scale vibration characteristic 701 and the laser vibration characteristic 702.

In the above description, the case where the rotational vibration about the X axis (FIG. 2) is generated in the Y table 104 has been described. However, even in a case where the rotational vibration about the Y axis or the rotational vibration about the Z axis is generated in the Y table 104, the frequency 703 of the rotational vibration of the Y table 104 can be similarly calculated.

For the calculation of the frequency 703 of the rotational vibration of the Y table 104, not only a method using the Fourier transform but also a method of measuring a frequency characteristic of the X table 102 to be controlled, a method of identifying a frequency so that a model output and a position detection signal match by using a transfer function model of vibration, a method of calculating in a learning manner by using artificial intelligence (AI), and the like may be used.

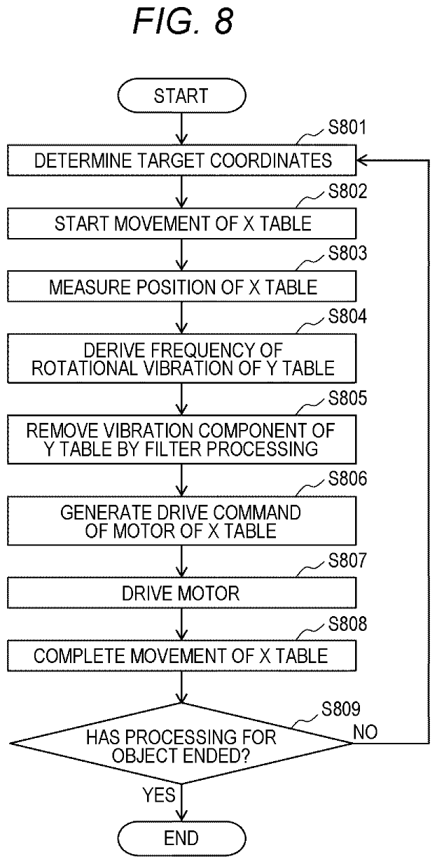

FIG. 8 is a flowchart illustrating processing of moving the X table 102 that is a floating stage by the stage apparatus according to the present embodiment.

In processing 5801, the computer system 601 determines coordinates (target coordinates) of the position to move the X table 102 based on designated coordinates on the object (for example, a semiconductor wafer) placed on the top table 101. The designated coordinates on the object are, for example, coordinates designated by a user of the stage apparatus or an apparatus coupled to the stage apparatus, and can be one of coordinates of a position on the object that the user desires to observe.

In processing 5802, the computer system 601 generates a drive command of the motor 200 based on the current coordinates and the target coordinates of the X table 102, and drives the motor 200 to start the movement of the X table 102.

In processing 5803, the computer system 601 measures the position of the X table 102 during the movement with the linear scale 300. When the linear scale 300 performs measurement in the six-axial directions (translation directions of X axis, Y axis, and Z axis and rotation directions of θx axis, θy axis, and θz axis) of the X table 102, the computer system 601 can calculate the position and the posture in the six-axial directions of the X table 102.

In processing 5804, the computer system 601 derives the frequency 703 of the rotational vibration of the Y table 104 by using the measurement value of the laser interferometer 600 and the measurement value of the linear scale 300 according to the method described with reference to FIG. 7.

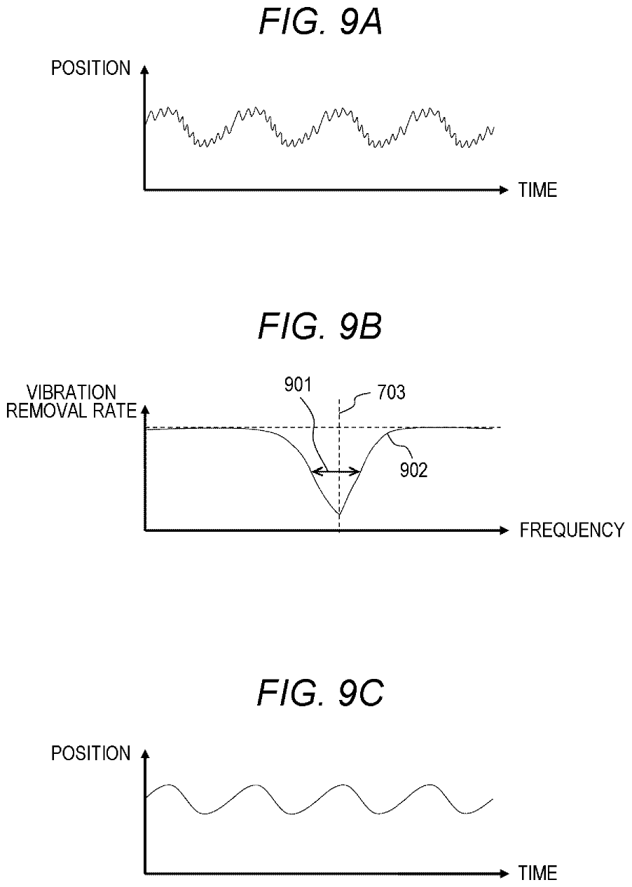

In processing 5805, the computer system 601 performs filter processing on the measurement value of the linear scale 300 to remove the component of the frequency 703 of the rotational vibration of the Y table 104 from the measurement value (signal indicating the position of the X table 102) of the linear scale 300. This filter processing will be described later with reference to FIGS. 9A to 9C. Note that the computer system 601 may perform the filter processing on the measurement value of the linear scale 300 in only one axial (for example, the Y axis) direction among the six-axial directions, or may perform the filter processing on the measurement value of the linear scale 300 in all the six-axial directions.

In processing 5806, the computer system 601 generates a drive command of the motor 200 that drives the X table 102. The computer system 601 calculates a drive command of the motor 200 that drives the X table 102 in at least one axial direction among the six-axial directions (translation directions of X axis, Y axis, and Z axis and rotation directions of θx axis, θy axis, and θz axis) from the measurement value of the linear scale 300 on which the filter processing is performed by using a feedback control method. For the calculation of the feedback control, for example, an existing control rule such as PID control can be used. In this way, the computer system 601 can obtain at least one of a translation distance and a rotation angle of the X table 102 when moving the X table 102.

In processing 5807, the computer system 601 drives the motor 200 based on the generated drive command, controls the position and posture of the X table 102, and moves the X table 102.

Processing 5803 to processing 5807 are periodically executed during the movement of the X table 102.

In processing 5808, the computer system 601 completes the movement of the X table 102 when the X table 102 has reached the target coordinates. When the movement of the X table 102 is completed, for example, processing for the object such as observation of the object (for example, a semiconductor wafer) is executed.

In processing 5809, the computer system 601 determines whether the processing for the object has ended. For example, the computer system 601 can determine whether the processing for the object has ended based on information provided via the user of the stage apparatus or the apparatus coupled to the stage apparatus. When the processing for the object has not been ended, the processing returns to the processing 5801.

Hereinafter, the filter processing executed in the processing 5805 of the flowchart illustrated in FIG. 8 will be described with reference to FIGS. 9A to 9C. As described above, the computer system 601 performs filter processing of removing the component of the frequency 703 of the rotational vibration of the Y table 104 from the measurement value (signal indicating the position of the X table 102) of the linear scale 300.

FIG. 9A is a diagram illustrating an example of a measurement value of the linear scale 300 before the computer system 601 performs the filter processing. The position of the X table 102 measured by the linear scale 300 is represented by a waveform in which a minute vibration component caused by the rotational vibration of the Y table 104 is superimposed on the rotational vibration of the X table 102.

FIG. 9B is a diagram illustrating an example of a filter frequency characteristic 902 of the filter processing performed by the computer system 601. The filter frequency characteristic 902 can be determined by using the frequency 703 of the rotational vibration of the Y table 104 and a width 901 of the frequency 703 of the rotational vibration. The width 901 of the frequency 703 of the rotational vibration can be arbitrarily determined. The filter frequency characteristic 902 has a characteristic of reducing a frequency component (a frequency component determined by the width 901) in the vicinity of the frequency 703 of the rotational vibration of the Y table 104. Any existing filter, for example, a notch filter can be used as a digital filter having the filter frequency characteristic 902.

FIG. 9C is a diagram illustrating an example of measurement value of the linear scale 300 after the computer system 601 performs the filter processing. The computer system 601 removes the component of the frequency 703 of the rotational vibration of the Y table 104 from the measurement value of the linear scale 300 by performing filter processing having the filter frequency characteristic 902 illustrated in FIG. 9B on the measurement value of the linear scale 300 illustrated in FIG. 9A. In the measurement value of the linear scale 300 illustrated in FIG. 9, the minute vibration component caused by the rotational vibration of the Y table 104, which is seen in FIG. 9A, is removed, and only the vibration component caused by the rotational vibration of the X table 102 remains.

The computer system 601 moves the X table 102 based on the measurement value of the linear scale 300 subjected to the filter processing as illustrated in FIG. 9C (processing 5806 and processing 5807 in FIG. 8). Therefore, the stage apparatus according to the present embodiment can reduce the influence of the rotational vibration of the Y table 104, can accurately control the position and the posture of the X table 102, and can reduce the residual vibration of the X table 102, thereby improving the throughput.

### Second Embodiment

A stage apparatus according to a second embodiment of the present invention will be described. Hereinafter, the stage apparatus according to the present embodiment will be mainly described in terms of differences from the stage apparatus according to the first embodiment.

In the present embodiment, the frequency 703 of the rotational vibration of the Y table 104 is known from previous measurement or structural analysis. The frequency 703 of the rotational vibration of the Y table 104 can be obtained in advance by a method of actual measurement by a percussion test, measurement of a vibration mode, or the like, or a method of calculation using a three-dimensional analysis tool or the like.

In the stage apparatus according to the present embodiment, since the frequency 703 of the rotational vibration of the Y table 104 is known in advance, the measurement of the position of the first portion of the X table 102 by the laser interferometer 600 can be omitted. Information on the frequency 703 of the rotational vibration of the Y table 104 is stored in the computer system 601. The computer system 601 can also store a vibration frequency map in which the frequency 703 of the rotational vibration of the Y table 104 is recorded.

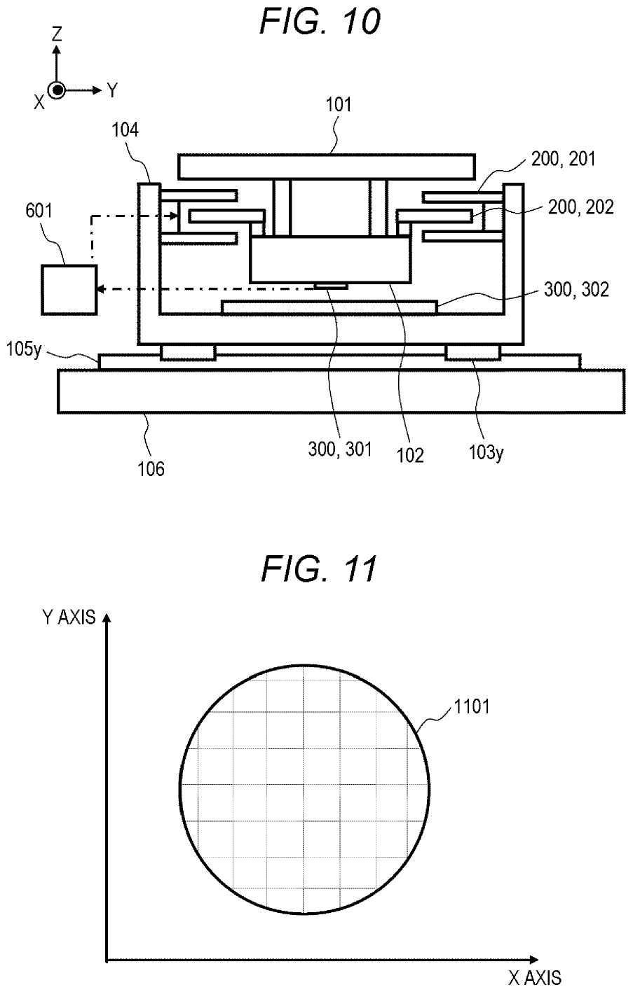

FIG. 10 is a diagram illustrating a configuration of the stage apparatus according to the present embodiment. The stage apparatus according to the present embodiment has the same configuration as the stage apparatus (FIG. 6) according to the first embodiment, but differs from the stage apparatus according to the first embodiment in that the stage apparatus does not include the laser interferometer 600 (reflecting mirror 602 and light source 605).

FIG. 11 is a diagram illustrating an example of a vibration frequency map 1101 in which information on the frequency 703 of the rotational vibration of the Y table 104 is recorded. In the stage apparatus, it is conceivable that a load or the posture of the stage (Y table 104) changes according to the stage coordinates (coordinates on the Y table 104), and the frequency 703 of the rotational vibration changes. Therefore, the frequency 703 of the rotational vibration may be recorded in the vibration frequency map 1101 for each stage coordinate, and the component of the frequency 703 of the rotational vibration removed by the filter processing may be changed according to the stage coordinates.

FIG. 11 illustrates an example of the vibration frequency map 1101 in which the frequency 703 of the rotational vibration of the Y table 104 is recorded for each stage coordinate. In the example illustrated in FIG. 11, the vibration frequency map 1101 has a circular shape reflecting the shape of the semiconductor wafer as the object. Note that, in FIG. 11, the vibration frequency map 1101 is represented in two dimensions of the X axis and the Y axis, but the vibration frequency map 1101 can also be represented in multiple dimensions by using directions such as a Z axis, a θx axis, a θy axis, and a θz axis.

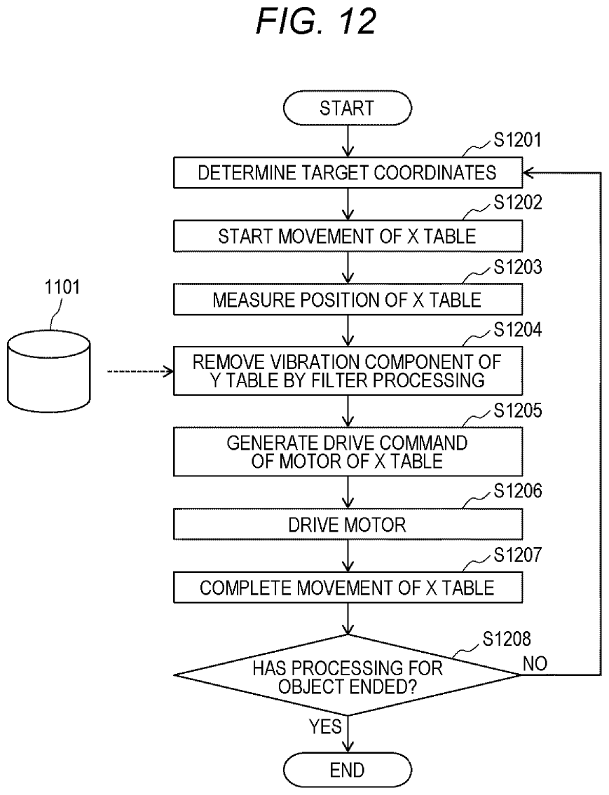

FIG. 12 is a flowchart illustrating processing of moving the X table 102 that is a floating stage by the stage apparatus according to the present embodiment.

Processing 51201 to processing 51203 are the same as the processing 5801 to the processing 5803 illustrated in FIG. 8.

In processing 51204, the computer system 601 performs filter processing on the measurement value of the linear scale 300, and removes the component of the frequency 703 of the rotational vibration of the Y table 104 from the measurement value (signal indicating the position of the X table 102) of the linear scale 300, similarly to the processing 5805 illustrated in FIG. 8 in the first embodiment. However, since the computer system 601 stores the frequency 703 of the rotational vibration of the Y table 104 obtained in advance, the same filter processing as in the first embodiment is performed by using the stored frequency 703 of the rotational vibration of the Y table 104. In a case where the component of the frequency 703 of the rotational vibration removed by the filter processing is changed according to the stage coordinates, the computer system 601 uses the information recorded in the vibration frequency map 1101.

Processing 51205 to processing 51208 are the same as the processing 5806 to the processing 5809 illustrated in FIG. 8.

Similarly to the stage apparatus according to the first embodiment, the stage apparatus according to the present embodiment can reduce the influence of the rotational vibration of the Y table 104, can accurately control the position and the posture of the X table 102, and can reduce the residual vibration of the X table 102, thereby improving the throughput.

### Third Embodiment

The stage apparatuses according to the first embodiment and the second embodiment reduce the influence of the vibration of the Y table 104 on the X table 102 by passive control. The stage apparatus according to a third embodiment of the present invention reduces the influence of the vibration of the Y table 104 on the X table 102 by active control.

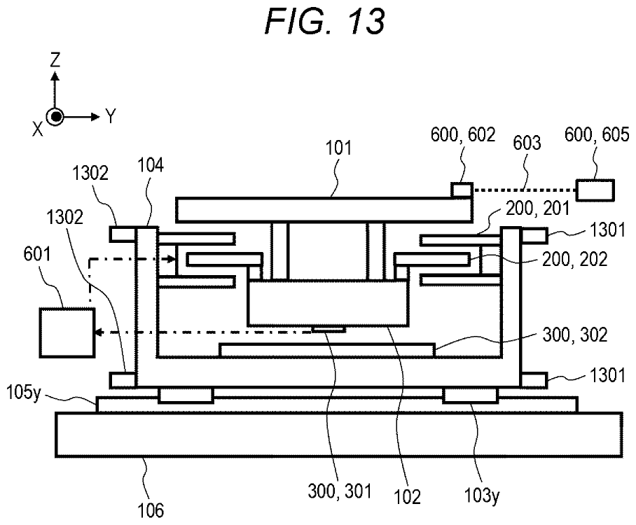

FIG. 13 is a diagram illustrating a configuration of a stage apparatus according to the present embodiment. The stage apparatus according to the present embodiment further includes a vibration sensor 1301 and an actuator 1302 for damping minute vibration of the Y table 104 in the stage apparatus (FIG. 6) according to the first embodiment.

The vibration sensor 1301 detects the vibration of the Y table 104. As the vibration sensor 1301, an arbitrary vibration detection apparatus can be used, and for example, an acceleration sensor, a strain sensor, a laser displacement meter, an electrostatic capacitance sensor, or the like can be used. The vibration of the Y table 104 can be detected by detecting at least one of the position, speed, and acceleration of the Y table 104.

The actuator 1302 can drive the Y table 104. As the actuator 1302, an arbitrary actuator, for example, an actuator using a piezoelectric element or the like can be used. Furthermore, the actuator 1302 can also be configured by a planar motor including a permanent magnet and a coil.

The computer system 601 performs feedback control to actively control the vibration of the Y table 104. That is, the computer system 601 uses the information on the vibration of the Y table 104 detected by the vibration sensor 1301 to generate a drive signal for driving the actuator 1302 so as to dampen the vibration of the Y table 104, and drives the actuator 1302 with the drive signal to control the vibration of the Y table 104.

The number of the vibration sensors 1301 and the number of the actuators 1302 can be arbitrarily determined, and may be one or more so as to be able to control at least one-axial direction among six-axial (X axis, Y axis, Z axis, θx axis, θy axis, and θz axis) directions.

The stage apparatus according to the present embodiment can reduce the influence of the rotational vibration of the Y table 104 by the feedback control using the vibration sensor 1301 and the actuator 1302, can accurately control the position and the posture of the X table 102, and can reduce the residual vibration of the X table 102, thereby improving the throughput.

### Fourth Embodiment

Similarly to the stage apparatus according to the third embodiment, a stage apparatus according to a fourth embodiment of the present invention reduces the influence of the vibration of the Y table 104 on the X table 102 by the active control.

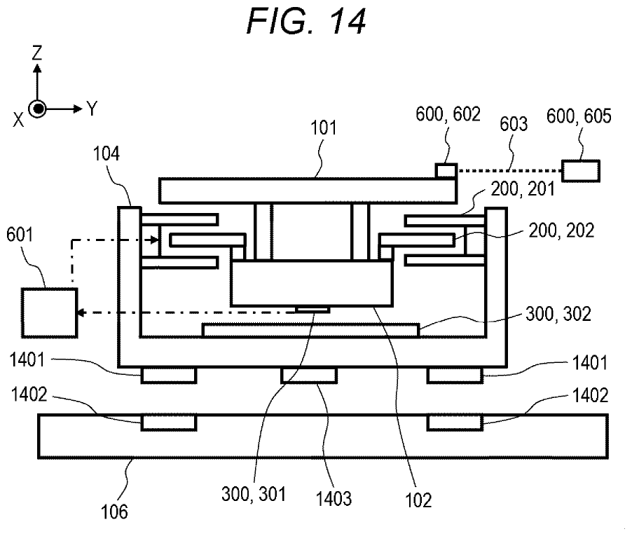

FIG. 14 is a diagram illustrating a configuration of a stage apparatus according to the present embodiment. In the stage apparatus according to the present embodiment, the Y table 104 is a floating stage in the stage apparatus (FIG. 6) according to the first embodiment. That is, the stage apparatus according to the present embodiment does not include the guide carriage 103y and the linear guide 105y in the stage apparatus according to the first embodiment, but includes a motor mover 1401, a motor stator 1402, and a position detection sensor 1403.

The motor mover 1401 and the motor stator 1402 apply a floating force and a propulsion force in the six-axial (X axis, Y axis, Z axis, θx axis, θy axis, and θz axis) directions to the Y table 104 by the electromagnetic force, and the Y table 104 is set as a floating stage. Note that the motor mover 1401 and the motor stator 1402 may have a planar floating configuration in which one includes a permanent magnet and the other includes a coil.

The position detection sensor 1403 measures the position of the Y table 104. An arbitrary apparatus can be used as the position detection sensor 1403, and for example, a position measurement sensor such as a linear scale or a laser interferometer, or a current sensor such as a Hall element may be used.

Since the stage apparatus according to the present embodiment illustrated in FIG. 14 includes the drive mechanism (the motor mover 1401 and the motor stator 1402) capable of controlling the Y table 104 in the six-axial directions, the rotational vibration of the Y table 104 can be actively reduced without using the vibration sensor or the actuator (third embodiment). Therefore, the stage apparatus according to the present embodiment can more effectively reduce the influence of the vibration of the Y table 104 on the X table 102 by the active control.

By using the passive damping configuration described in the first embodiment and the second embodiment in combination with the active damping configuration described in the third embodiment and the fourth embodiment, it is also possible to realize a stage apparatus that further effectively reduces the vibration of the X table 102.

### Fifth Embodiment

In a fifth embodiment, a charged particle beam apparatus and an optical inspection apparatus according to an embodiment of the present invention will be described. The charged particle beam apparatus and the optical inspection apparatus according to the present embodiment include the stage apparatus described in any one of the first to fourth embodiments.

First, the charged particle beam apparatus according to the present embodiment will be described.

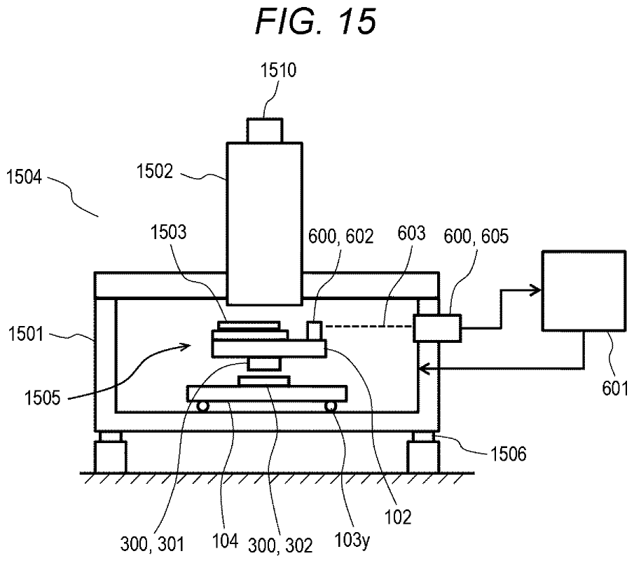

FIG. 15 is a diagram illustrating a configuration example of the charged particle beam apparatus according to the present embodiment. Hereinafter, as an example, a semiconductor measurement apparatus 1504 will be described as the charged particle beam apparatus. FIG. 15 is a schematic cross-sectional diagram of the semiconductor measurement apparatus 1504.

The semiconductor measurement apparatus 1504 which is the charged particle beam apparatus according to the present embodiment is, for example, a scanning electron microscope such as a length measuring SEM, and can inspect an object 1503 such as a semiconductor wafer by using a charged particle beam (electron beam). The semiconductor measurement apparatus 1504 includes a stage apparatus 1505 that positions the object 1503, a vacuum chamber 1501 that accommodates the stage apparatus 1505, and a lens barrel 1502.

The stage apparatus 1505 is a stack-type stage apparatus including the floating stage described in the first to fourth embodiments.

The vacuum chamber 1501 is decompressed by a vacuum pump (not illustrated), and an inside thereof is brought into a vacuum state of a pressure lower than an atmospheric pressure. The vacuum chamber 1501 is supported by using a damping mount 1506 to prevent vibrations from transmitting from a floor.

The lens barrel 1502 is a lens barrel of a charged particle beam that is installed in the vacuum chamber 1501, includes a charged particle beam source as a beam source 1510, and irradiates the object 1503 with the charged particle beam. In the present embodiment, the beam source 1510 is an electron source, and the lens barrel 1502 is an electron optical system lens barrel that irradiates the object 1503 with an electron beam.

The semiconductor measurement apparatus 1504 positions the object 1503 by the stage apparatus 1505, irradiates the object 1503 with an electron beam from the lens barrel 1502, and images a pattern formed on the object 1503, thereby measuring a line width of a minute pattern on the order of nanometers and evaluating shape accuracy. The stage apparatus 1505 measures the position of the stage by at least one of the laser interferometer 600 and the linear scale 300, and performs feedback control calculation by the computer system 601.

Next, an optical inspection apparatus according to the present embodiment will be described. The optical inspection apparatus according to the present embodiment can inspect the object 1503 by using light. The optical inspection apparatus according to the present embodiment has the same configuration as the charged particle beam apparatus illustrated in FIG. 15, but the lens barrel 1502 is different from the charged particle beam apparatus. The lens barrel 1502 of the optical inspection apparatus according to the present embodiment is an optical lens barrel that includes a light source as the beam source 1510 and irradiates the object 1503 with a light beam.

In the stage apparatus, the charged particle beam apparatus, and the optical inspection apparatus according to the present embodiment, the residual vibration of the X table 102 (floating stage) due to minute rotational vibration of the Y table 104 can be reduced, and the accuracy of measurement on the order of nanometers such as semiconductor measurement can be improved. In addition, since the time for waiting for the attenuation of the residual vibration after the movement of the floating stage can be shortened, this also contributes to improvement of the throughput.

Note that the present invention is not limited to the above-described embodiments, and various modifications are possible. For example, the above-described embodiments have been described in detail for easy understanding of the present invention, and the present invention is not necessarily limited to an aspect including all the described configurations. In addition, a part of the configuration of a certain embodiment can be replaced with the configuration of another embodiment, and the configuration of another embodiment can be added to the configuration of a certain embodiment. In addition, a part of the configuration of each embodiment can be deleted, or another configuration can be added or replaced.

What is claimed is:

1. A stage apparatus comprising:
a base;
a first table that is movable on the base;
a second table that is movable in a state of floating above the first table and includes a first portion and a second portion below the first portion;
a first position measuring device that measures a position of the first portion of the second table;
a second position measuring device that measures a position of the second portion of the second table;
a motor that drives the second table; and
a computer that controls the motor,
wherein the computer drives the second table based on information on the position of the first portion measured by the first position measuring device and information on the position of the second portion measured by the second position measuring device.

2. The stage apparatus according to claim 1, wherein
the computer derives a frequency of rotational vibration of the first table based on a measurement value of the first position measuring device and a measurement value of the second position measuring device, and drives the second table by using the frequency.

3. The stage apparatus according to claim 1, wherein
the computer obtains at least one of a translation distance and a rotation angle of the second table based on a measurement value of the first position measuring device and a measurement value of the second position measuring device.

4. The stage apparatus according to claim 2, wherein
the computer performs filter processing of removing a component of the frequency from the measurement value of the second position measuring device, and drives the second table by using the measurement value of the second position measuring device subjected to the filter processing.

5. The stage apparatus according to claim 2, wherein
the computer calculates a drive signal for offsetting a component of the frequency with respect to the motor, and applies the drive signal to the motor to drive the second table.

6. The stage apparatus according to claim 1, wherein
the first portion of the second table is a portion above a rotation center while the second table is floating, and
the second portion of the second table is a portion below the rotation center.

7. The stage apparatus according to claim 6, wherein
the computer derives a frequency of rotational vibration of the first table based on a frequency characteristic of a measurement value of the first position measuring device and a frequency characteristic of a measurement value of the second position measuring device, and drives the second table by using the frequency.

8. The stage apparatus according to claim 1, wherein
the first position measuring device is a laser interferometer including a mirror installed on an upper portion of the second table, and
the second position measuring device is an optical sensor that measures a relative position of the second table with respect to the first table.

9. The stage apparatus according to claim 1, wherein
a frequency of rotational vibration of the first table is known in advance, and
the computer stores a map in which the frequency is recorded for each coordinate on the first table.

10. The stage apparatus according to claim 1, further comprising:
a sensor that detects vibration of the first table; and
an actuator that drives the first table,
wherein the computer drives the actuator to dampen the vibration of the first table by using information detected by the sensor.

11. A stage apparatus comprising:
a base;
a first table that is movable on the base;
a second table that is movable in a state of floating above the first table;
a position measuring device that measures a relative position of the second table with respect to the first table;
a motor that drives the second table; and
a computer that controls the motor,
wherein a frequency of rotational vibration of the first table is known in advance,
the computer stores information on the frequency, and
the computer performs filter processing of removing a component of the frequency from a measurement value of the position measuring device, and drives the second table by using the measurement value of the position measuring device subjected to the filter processing.

12. A charged particle beam apparatus comprising:
a stage apparatus;
a chamber that accommodates the stage apparatus; and
a lens barrel that is installed in the chamber and includes a charged particle beam source,
wherein the stage apparatus is the stage apparatus according to claim 1.

13. An optical inspection apparatus comprising:
a stage apparatus;
a chamber that accommodates the stage apparatus; and
a lens barrel that is installed in the chamber and includes a light source,
wherein the stage apparatus is the stage apparatus according to claim 1.
